(19) United States
(12) Patent Application Publication
(10) Pub. No.: US 2026/0008944 A1
(43) Pub. Date: Jan. 8, 2026

(54) METHOD FOR PRODUCING A DIE ATTACH ADHESIVE FILM SHEET

(71) Applicant: Henkel AG & Co. KGaA, Duesseldorf (DE)

(72) Inventors: Jihong Deng, Tustin, CA (US); Israel Hernandez, Anaheim, CA (US); Jeffrey Grey, Orange, CA (US); Thao Q Vo-Le, Irvine, CA (US); Luciano Covarrubias, South Gate, CA (US); Raul Cortes, JR., South Gate, CA (US)

(21) Appl. No.: 19/078,526

(22) Filed: Mar. 13, 2025

Related U.S. Application Data
(63) Continuation of application No. PCT/US2023/032977, filed on Sep. 18, 2023.
(60) Provisional application No. 63/407,755, filed on Sep. 19, 2022.

(51) Int. Cl. C09J 7/40; C09J 5/00; C09J 9/02; C09J 11/02; H01L 21/78; H01L 23/00

(52) U.S. Cl. CPC C09J 7/405; C09J 5/00; C09J 9/02; C09J 11/02; H01L 21/78; H01L 24/29; H01L 24/83; C09J 2203/326; C09J 2301/408; C09J 2467/005; H01L 2224/2929; H01L 2224/29339; H01L 2224/29386; H01L 2224/8385

(57) ABSTRACT

Provided herein is a method for producing a die attach adhesive film sheet, comprising:
Providing a first release substrate layer, a die attach adhesive layer, and a dicing tape layer, and joining the first release substrate layer, the die attach adhesive layer, and the dicing tape layer in that order to form a multi-layer structure;
Working the multi-layer structure to form a circular preformed die attach adhesive film sheet, wherein during said working the first release substrate receives a z-directional indentation therein; and
Removing the first release substrate with the z-directional indentation therein from the die attach adhesive layer, and placing in its stead a second release substrate in contact with the die attach adhesive layer.

### BACKGROUND

### Field

Provided herein is a method for producing a die attach adhesive film sheet.

### Brief Description of Related Technology

U.S. Pat. No. 8,470,115 (Tanaka) is directed to and claims a method for producing a semiconductor device, comprising:
peeling off a laminate, including an adhesive layer, a tacky layer and a substrate film in an adhesive sheet from a release substrate of the adhesive sheet, the adhesive sheet comprising the release substrate, the adhesive layer, the tacky layer, and the substrate film, laminated in order, and sticking the laminate through the adhesive layer to a semiconductor wafer to give a semiconductor wafer having the laminate;
dicing the semiconductor wafer having the laminate to give a semiconductor element having a laminate with a pre-determined size;
irradiating the tacky layer with high energy beams to lower the tack strength of the tacky layer to the adhesive layer, and then peeling the tacky layer and the substrate film from the adhesive layer to give a semiconductor element having the adhesive layer; and
bonding the semiconductor element having the adhesive layer through the adhesive layer to a support member for mounting a semiconductor element, wherein the adhesive layer has a pre-determined first plane shape and is formed on part of the release substrate;
   wherein a first incision is formed in the release substrate from a side bringing contact with the adhesive layer along the periphery of the plane shape of the adhesive layer;
   wherein the release substrate has a thickness of 30-50 μm; and
   wherein the first incision has a depth of greater than zero, and less than 25 μm.

In the '115 patent, the named inventors recognized in FIGS. 15 and 25 therein and accompanying disclosure that defects occur when practicing the technique so-discussed. (See '115 patent, col. 3, lines 31-40; col. 4, lines 1-10; FIGS. 1 and 2 hereof.)
The present inventors found, however, that the tacky-adhesive layer 12 in the adhesive sheet obtained in the precut processing in which the inserting position of the precutting blade C is set deep, as shown in FIG. 15, is bitten by an incision E in the release substrate 10, and an interface between the release substrate 10 and the tacky-adhesive layer 12 is sealed. The present inventors further found that when the adhesive sheet is laminated on a wafer while this state is kept, it is difficult to peel off the tacky-adhesive layer 12 from the release substrate 10, and peel defect easily occurs.
The present inventors found, however, that the adhesive layer 214 and the tacky layer 222 in the adhesive sheet obtained in the precut processing in which the inserting position of the precutting blade C is set deep, as shown in FIG. 25, is bitten by an incision F in the release substrate 212, and an interface between the release substrate 212 and the adhesive layer 214 is sealed. The present inventors further found that when the adhesive sheet is laminated on a wafer while this state is kept, it is difficult to peel off the adhesive layer 214 from release substrate 212, and peel defect easily occurs.

U.S. Pat. No. 8,465,615 (Tanaka) is directed to and claims a method for producing a semiconductor wafer having a laminate, comprising:
peeling off a release substrate from an adhesive sheet comprising the release substrate, a substrate film, and a lacky-adhesive layer placed between the release substrate and the substrate film, to give the laminate including the substrate film and the tacky-adhesive layer; and
sticking the tacky-adhesive layer of the laminate to a semiconductor wafer, wherein:
an annular incision has been formed in the release substrate of the adhesive sheet from the tacky-adhesive layer side of the release substrate,
the release substrate has a thickness of 30-50 μm,
the tacky-adhesive layer covers a whole inner surface of the incision in the release substrate,
the incision has a depth of more than zero, and less than 25 μm, and
a lamination of the laminate to the semiconductor wafer is continuously performed in an automatic step.

The relevant FIGs. and disclosure of the '155 patent are likewise present in the '615 patent.

Unlike the disclosures in the prior two recited methods, where incisions are formed in the adhesive sheet during processing, and in one instance an irradiating step is introduced, the need still exists for a manufacturing process that produces such an adhesive sheet with greater reproducibility and fewer defective parts.

### SUMMARY

That need has been satisfied here.

Provided herein in one aspect is a method for producing a die attach adhesive film sheet. In the method of this aspect, the steps include:
A. Providing a first release substrate layer, a die attach adhesive layer, and a dicing tape layer, and joining the first release substrate layer, the die attach adhesive layer, and the dicing tape layer in that order to form a multi-layer structure;
B. Working the multi-layer structure to form a circular preformed die attach adhesive film sheet, wherein during said working the first release substrate receives a z-directional indentation therein; and
C. Removing the first release substrate with the z-directional indentation therein from the die attach adhesive layer, and placing in its stead a second release substrate in contact with the die attach adhesive layer.

Provided herein in another aspect is a method for producing a semiconductor chip. In the method of this aspect, the steps include:
A1. Providing a die attach adhesive film sheet made by the method whose steps are recited as A-C of the preceding numbered paragraph;
B1. Peeling away the second release substrate from the die attach adhesive film sheet to reveal the die attach adhesive film layer; and
C1. Providing a semiconductor wafer having a surface available for bonding and mating the surface of the semiconductor wafer available for bonding to the die attach adhesive film sheet through the die attach adhesive layer thereof.

### BRIEF DESCRIPTION OF THE DRAWINGS

FIG. 1 depicts FIG. 15 of U.S. Pat. No. 8,470,115 (Tanaka), as illustrative of a problem for which the present disclosure provides a solution.

FIG. 2 depicts FIG. 25 of U.S. Pat. No. 8,470,115 (Tanaka), as illustrative of a problem for which the present disclosure provides a solution.

FIG. 3 depicts a schematic of the method described by the present disclosure, in a two phase configuration.

FIG. 4 depicts a schematic of the method described by the present disclosure, in a one phase configuration.

### DETAILED DESCRIPTION

As noted above, provided herein in one aspect is a method for producing a die attach adhesive film sheet. In the method of this aspect, the steps include:
A. Providing a first release substrate layer, a die attach adhesive layer, and a dicing tape layer, and joining the first release substrate layer, the die attach adhesive layer, and the dicing tape layer in that order to form a multi-layer structure, such as a first multi-layer structure or a multi-layer structure (i) in a first format;
B. Working the multi-layer structure to form a circular preformed die attach adhesive film sheet, wherein during said working the first release substrate receives a z-directional indentation therein, wherein the z-direction indentation has a first diameter; and
C. Removing the first release substrate with the z-directional indentation therein from the die attach adhesive layer, and placing in its stead a second release substrate in contact with the die attach adhesive layer to form a second multi-layer structure or a multi-layer structure (ii) in a second format.

An additional step includes:
D. Working the multi-layer structure (ii) to receive a z-directional indentation in the second release substrate, wherein the z-directional indentation has a second diameter, wherein the second diameter is greater than the first diameter.

In some embodiments, the first release substrate is constructed from polyester, which optionally is coated by a release agent. The polyester should have a machine direction (i.e., the direction in which the substrate advances through the process) tensile strength higher than 130 MPa and a cross direction (i.e., the direction perpendicular to the direction in which the substrate advances through the process) tensile strength higher than 150 MPa, and a modulus between 500-600 Kpsi. When a release agent is used to coat the polyester release substrate, the release agent may be chosen from a host of materials such as crosslinkable silicones, waxes, and fatty esters. The release agent may be in liquid or solid form. When in liquid form it may be applied neat to the release substrate or first diluted in solution or dispersion and thereafter applied to the release substrate. Commercially available examples of the release substrates constructed from polyester, with or without a release agent coated thereon, include HOSTAPHAN from Mitsubishi, PRIMELINER from Loparex, and TEXCELL from Toray.

In some embodiments, the second release substrate is constructed from polyester, which optionally is coated by a release agent.

In some embodiments, the first release substrate is from about 35 μm to about 50 μm in thickness.

In some embodiments, the second release substrate is from about 35 μm to about 50 μm in thickness.

The second release substrate may be the same or different from the first release substrate. All of the features and characteristics of the first release substrate apply to the second release substrate as well. And to that end the first release substrate may be the same or different from the second release substrate.

In some embodiments, the dicing tape layer is constructed from a host of materials such as PVC, polyolefin or polyethylene, desirably polyolefin.

In some embodiments, the dicing tape layer is from about 80 microns to about 150 microns in thickness.

In some embodiments, the die attach adhesive layer comprises a curable matrix comprising at least one of epoxy resins; maleimide-containing, nadimide-containing and/or itaconimide-containing resins; and/or (meth)acrylate resins.

The epoxy resins may be chosen from epoxy resins based on bisphenol A, bisphenol F or bisphenol S, multifunctional epoxy resins based on phenol novolac resin, dicyclopentadiene-type epoxy resins, naphthalene-type epoxy resins, and the like. Other example epoxy-functionalized resins contemplated for use herein include the diepoxide of the cycloaliphatic alcohol, hydrogenated bisphenol A (commercially available as Epalloy 5000), a difunctional cycloaliphatic glycidyl ester of hexahydrophthalic anhydride (commercially available as Epalloy 5200), Epiclon EXA-835LV, Epiclon HP-7200L, and the like, as well as mixtures of any two or more thereof.

Commercially available examples of the bisphenol epoxies contemplated for use herein include bisphenol-F-type epoxies (such as RE-404-S from Nippon Kayaku, Japan, and EPICLON 830 (RE1801), 830S (RE1815), 830A (RE1826) and 830W from Dai Nippon Ink & Chemicals, Inc., and RSL 1738 and YL-983U from Resolution) and bisphenol-A-type epoxies (such as YL-979 and 980 from Resolution). Further examples of commercially available epoxy resins include Epon 828, Epon 826, Epon 862 (all from Hexion Co., Ltd.), DER 331, DER 383, DER 332, DER 330-EL, DER 331-EL, DER 354, DER 321, DER 324, DER 29, DER 353 (all from Dow Chemical Co.), JER YX8000, JER RXE21, JER YL 6753, JER YL6800, JER YL980, JER 825, and JER 630 (all from Japan Epoxy Resins Co).

The bisphenol epoxies available commercially from Dai Nippon and noted above are promoted as liquid undiluted epichlorohydrin-bisphenol F epoxies having much lower viscosities than conventional epoxies based on bisphenol A epoxies and have physical properties similar to liquid bisphenol A epoxies. Bisphenol F epoxy has lower viscosity than bisphenol A epoxies, all else being the same between the two types of epoxies, which affords a lower viscosity and thus a fast flow underfill sealant material. The Epoxy Equivalent Weight (EEW), which is the molecular weight divided by the number of epoxy groups of these four bisphenol F epoxies, is between 165 and 180. The viscosity at 25° C. is between 3,000 and 4,500 cps (except for RE1801 whose upper viscosity limit is 4,000 cps). The hydrolyzable chloride content is reported as 200 ppm for RE1815 and 830 W, and that for RE1826 as 100 ppm.

The bisphenol epoxies available commercially from Resolution and noted above are promoted as low chloride containing liquid epoxies. The bisphenol A epoxies have an EEW (g/eq) of between 180 and 195 and a viscosity at 25° C. of between 100 and 250 cP. The total chloride content for YL-979 is reported as between 500 and 700 ppm, and that for YL-980 as between 100 and 300 ppm. The bisphenol F epoxies have a EEW (g/eq) of between 165 and 180 and a viscosity at 25° C. of between 30 and 60. The total chloride content for RSL-1738 is reported as between 500 and 700 ppm, and that for YL-983U as between 150 and 350 ppm.

In addition to the bisphenol epoxies, other epoxy compounds are contemplated for use as the epoxy component of invention formulations. For instance, cycloaliphatic epoxies, such as 3,4-epoxycyclohexylmethyl-3,4-epoxycyclohexylcarbonate, can be used. Also monofunctional, difunctional or multifunctional reactive diluents may be used to adjust the viscosity and/or lower the glass transition temperature (Tg) of the resulting resin material. Exemplary reactive diluents include butyl glycidyl ether, cresyl glycidyl ether, o-cresyl glycidyl ether, polyethylene glycol glycidyl ether, polypropylene glycol glycidyl ether, and the like.

Other epoxy resins suitable for use herein include polyglycidyl derivatives of phenolic compounds, such as those available commercially under the tradename EPON, such as EPON 828, EPON 1001, EPON 1009, and EPON 1031 from Resolution; DER 331, DER 332, DER 334, and DER 542 from Dow Chemical Co.; and BREN-S from Nippon Kayaku. Other suitable epoxies include polyepoxides prepared from polyols and the like and polyglycidyl derivatives of phenol-formaldehyde novolacs, the latter of such as DEN 431, DEN 438, and DEN 439 from Dow Chemical. Cresol analogs are also available commercially under the tradename ARALDITE, such as ARALDITE ECN 1235, ARALDITE ECN 1273, and ARALDITE ECN 1299 from Ciba Specialty Chemicals Corporation. SU-8 is a bisphenol-A-type epoxy novolac available from Resolution. Polyglycidyl adducts of amines, aminoalcohols and polycarboxylic acids are also useful in this invention, commercially available resins of which include GLYAMINE 135, GLYAMINE 125, and GLYAMINE 115 from F.I.C. Corporation; ARALDITE MY-720, ARALDITE 0500, and ARALDITE 0510 from Ciba Specialty Chemicals and PGA-X and PGA-C from the Sherwin-Williams Co.

The epoxy resin may be in a liquid state and may exhibit a viscosity of no greater than 5,000 cP at 25° C. and at a shear rate of 1 s⁻¹, such as no greater than 2,000 cP at 25° C. and at a shear rate of 1 s⁻¹, desirably no greater than 1,000 cP at 25° C. and at a shear rate of 1 s⁻¹, and more desirably no greater than 500 cP at 25° C. and at a shear rate of 1 s⁻¹.

The epoxy resin component of the curable composition may further include a monofunctional epoxy resin. It has been surprisingly discovered that such a monoepoxide resin leads to improved retention of cured material properties as a function of time, possibly due to reaction with otherwise unreacted 2′ and even 3′ amines to limit further changes in cross-link density and/or network properties after onset of gelation. The monoepoxide resin may further react with available-OH groups on the epoxy backbone. Moreover, an improvement in thermal reliability is surprisingly observed with the addition of a monoepoxide resin, at least within certain loading concentrations relative to other epoxy resins.

Examples of monoepoxy resins include monoglycidyl ethers, such as phenyl glycidyl ether, alkyl phenol monoglycidyl ether, aliphatic monoglycidyl ether, alkyphenol mono glycidyl ether, alkylphenol monoglycidyl ether, 3-glycidoxypropyl trimethoxysilane, 3-glycidoxypropyl trimethoxysilane, 3-glycidoxypropylmethyldimethoxysilane, and o-cresyl glycidyl ether.

The monoepoxy resins (or, monofunctional epoxy resins) may have an epoxy group with an alkyl group of about 6 to about 28 carbon atoms, examples of which include C₆₋₂₈ alkyl glycidyl ethers, C₆₋₂₈ fatty acid glycidyl ethers, C₆₋₂₈ alkylphenol glycidyl ethers, and the like.

The maleimide-containing, nadimide-containing and/or itaconimide-containing resins may be chosen from a variety of materials,

In certain embodiments, the degree of substitution of imide moieties on the backbone of the first maleimide, nadimide or itaconimide is at least 0.8, such as at least 1, imide moieties per repeat unit of said backbone.

In certain embodiments, the maleimide, nadimide or itaconimide has the structure:

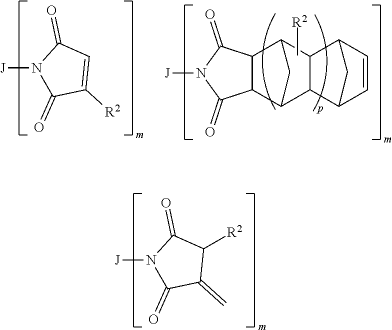

respectively, wherein:
m is 1-15,
p is 0-15,
each R² is independently selected from hydrogen or lower alkyl, and
J is a monovalent or a polyvalent radical selected from:
   aromatic hydrocarbyl or substituted aromatic hydrocarbyl species having in the range of about 6 up to about 300 carbon atoms, where the aromatic hydrocarbyl species is selected from aryl, alkylaryl, arylalkyl, aryalkenyl, alkenylaryl, arylalkynyl or alkynylaryl;
   aromatic hydrocarbylene or substituted aromatic hydrocarbylene species having in the range of about 6 up to about 300 carbon atoms, where the aromatic hydrocarbylene species are selected from arylene, alkylarylene, arylalkylene, arylalkenylene, alkenylarylene, arylalkynylene or alkynylarylene,
   heterocyclic or substituted heterocyclic species having in the range of about 6 up to about 300 carbon atoms,
   polysiloxane, or
   polysiloxane-polyurethane block copolymers, as well as combinations of one or more of the above with a linker selected from a covalent bond, —O—, —S—, —NR—, —NR—C(O)—, —NR—C(O)—O—, —NR—C(O)—NR—, —S—C(O)—, —S—C(O)—O—, —S—C(O)—NR—, —O—S(O)₂—, —O—S(O)₂—O—, —O—S(O)₂—NR—, —O—S(O)—, —O—S(O)—O—, —O—S(O)—NR—, —O—NR—C(O)—, —O—NR—C(O)—O—, O—NR—C(O)—NR, —NR—O—C(O)—, —NR—O—C(O)—O—, —NR—O—C(O)—NR—, —O—NR—C(S)—, —O—NR—C(S)—O—, —O—NR—C(S)—NR—, —NR—O—C(S)—, —NR—O—C(S)—O—, —NR—O—C(S)—NR—, —O—C(S)—, —O—C(S)—O—, —O—C(S)—NR—, —NR—C(S)—, —NR—C(S)—O—, —NR—C(S)—NR—, —S—S(O)₂—, —S—S(O)₂—O—, —S—S(O)₂—NR—, —NR—O—S(O)—, —NR—O—S(O)—O—, —NR—O—S(O)—NR—, —NR—O—S(O)₂—, —NR—O—S(O)₂—O—, —NR—O—S(O)₂—NR—, —O—NR—S(O)—, —O—NR—S(O)—O—, —O—NR—S(O)—NR—, —O—NR—S(O)₂—O—, —O—NR—S(O)₂—NR—, —O—NR—S(O)₂—, —O—P(O)R₂—, —S—P(O)R₂—, or —NR—P(O)R₂—; where each R is independently hydrogen, alkyl or substituted alkyl.

In some embodiments of the present invention, J of the above-described maleimide, nadimide or itaconimide is heterocyclic, oxyheterocyclic, thioheterocyclic, aminoheterocyclic, carboxyheterocyclic, oxyaryl, thioaryl, aminoaryl, carboxyaryl, heteroaryl, oxyheteroaryl, thioheteroaryl, aminoheteroaryl, carboxyheteroaryl, oxyalkylaryl, thioalkylaryl, aminoalkylaryl, carboxyalkylaryl, oxyarylalkyl, thioarylalkyl, aminoarylalkyl, carboxyarylalkyl, oxyarylalkenyl, thioarylalkenyl, aminoarylalkenyl, carboxyarylalkenyl, oxyalkenylaryl, thioalkenylaryl, aminoalkenylaryl, carboxyalkenylaryl, oxyarylalkynyl, thioarylalkynyl, aminoarylalkynyl, carboxyarylalkynyl, oxyalkynylaryl, thioalkynylaryl, aminoalkynylaryl or carboxyalkynylaryl, oxyarylene, thioarylene, aminoarylene, carboxyarylene, oxyalkylarylene, thioalkylarylene, aminoalkylarylene, carboxyalkylarylene, oxyarylalkylene, thioarylalkylene, aminoarylalkylene, carboxyarylalkylene, oxyarylalkenylene, thioarylalkenylene, aminoarylalkenylene, carboxyarylalkenylene, oxyalkenylarylene, thioalkenylarylene, aminoalkenylarylene, carboxyalkenylarylene, oxyarylalkynylene, thioarylalkynylene, aminoarylalkynylene, carboxy arylalkynylene, oxyalkynylarylene, thioalkynylarylene, aminoalkynylarylene, carboxyalkynylarylene, heteroarylene, oxyheteroarylene, thioheteroarylene, aminoheteroarylene, carboxyheteroarylene, heteroatom-containing di- or polyvalent cyclic moiety, oxyheteroatom-containing di- or polyvalent cyclic moiety, thioheteroatom-containing di- or polyvalent cyclic moiety, aminoheteroatom-containing di- or polyvalent cyclic moiety, or a carboxyheteroatom-containing di- or polyvalent cyclic moiety.

In certain embodiments, the backbone of the maleimide, nadimide or itaconimide contemplated for use herein contains straight or branched chain hydrocarbyl segments, wherein each hydrocarbyl segment has at least 30 carbons, thereby enhancing the flexibility thereof.

Examples of the maleimide, nadimide, or itaconamide include:

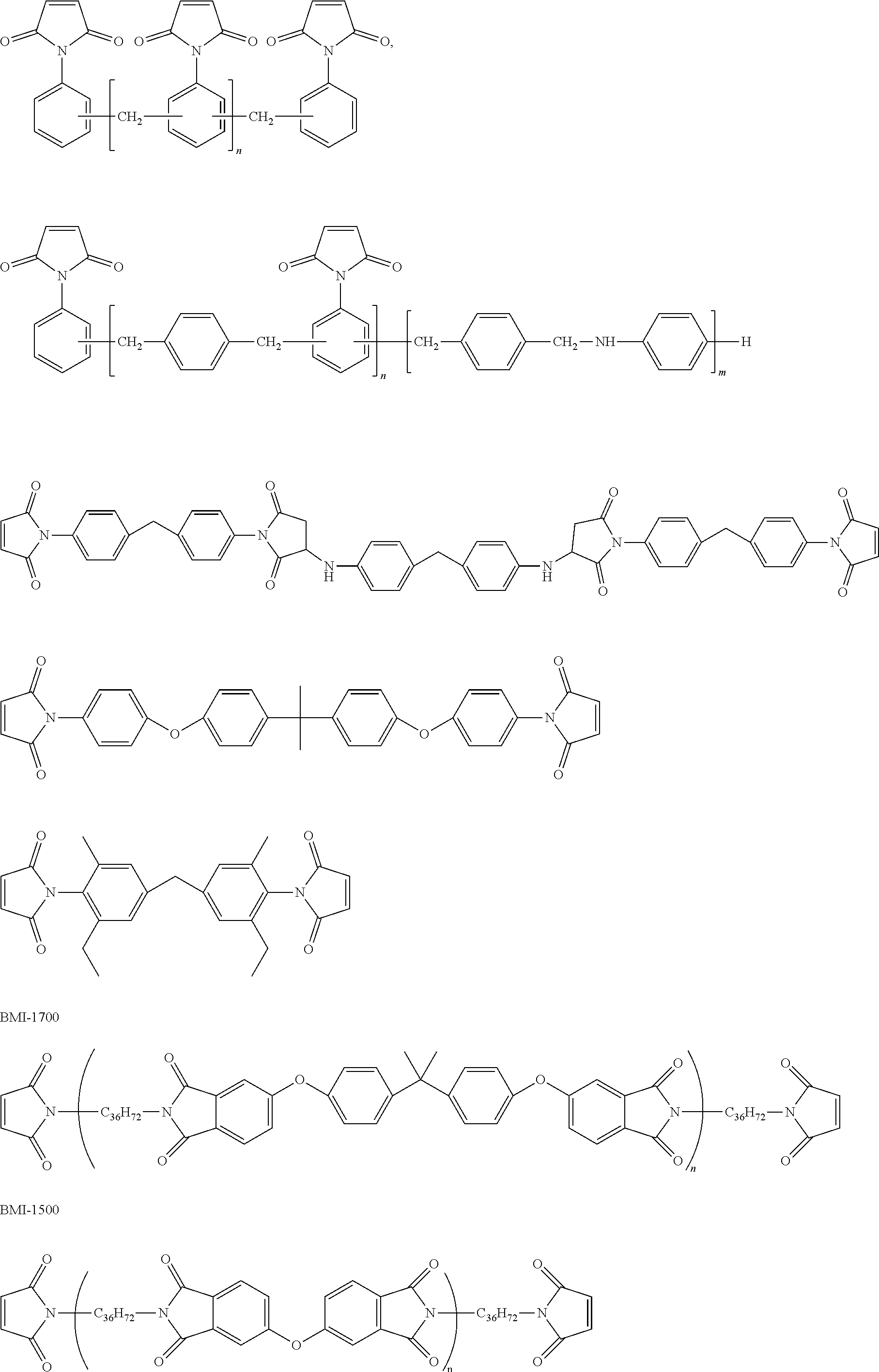

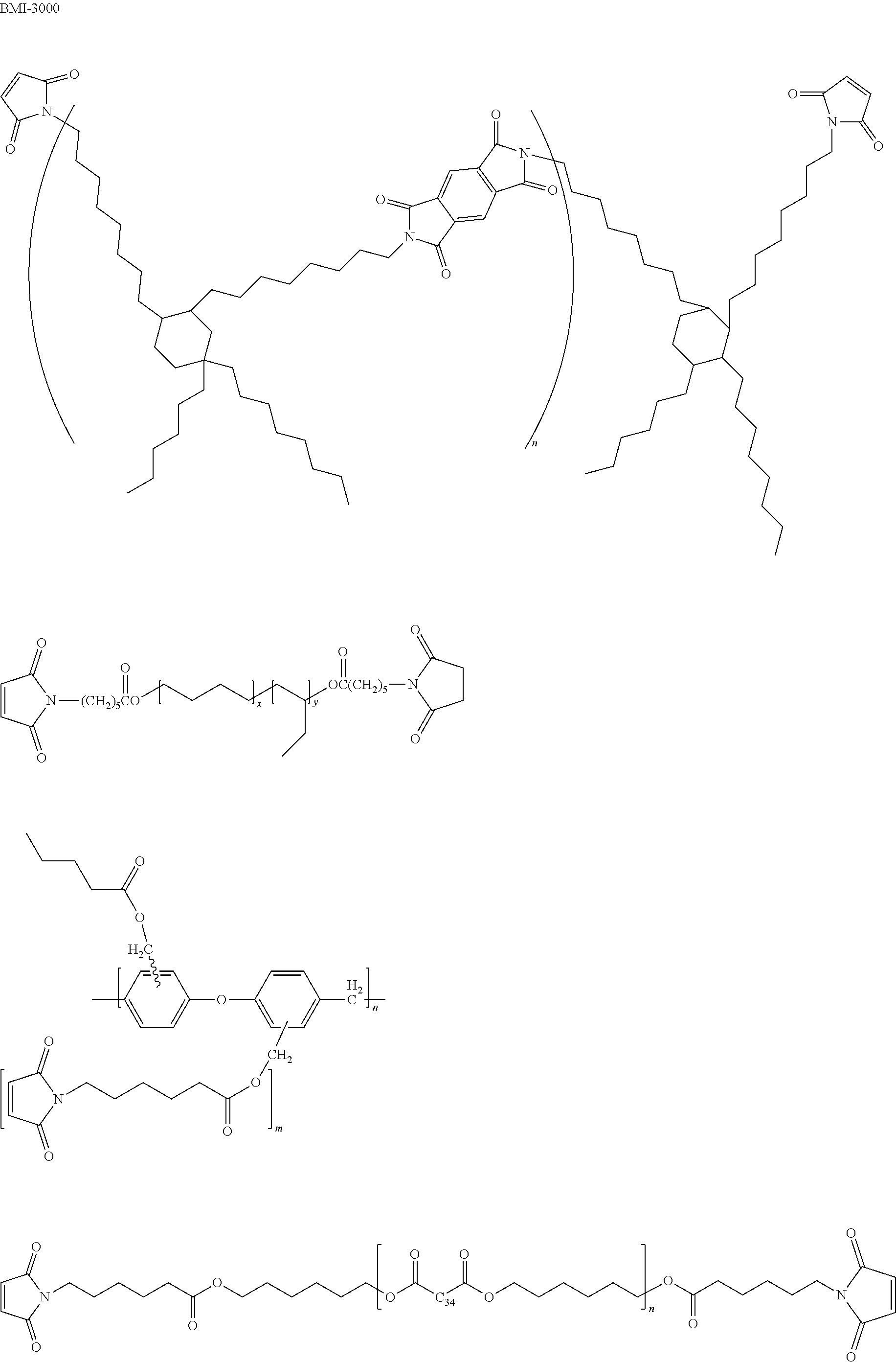

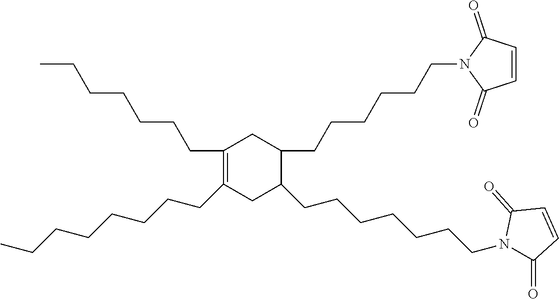 [SMILES: CCCCCCCCC1=C(CCCCCCC)CC(CCCCCCN2C(=O)C=CC2=O)C(CCCCCCCN2C(=O)C=CC2=O)C1]

In these structures, as appropriate, m and n are in the range of 0 to 10, and x and y are in the range of 0 to 50.

The (meth)acrylate resins may be chosen from a variety of materials, including monofunctional (meth)acrylates, difunctional (meth)acrylates, trifunctional (meth)acrylates, polyfunctional (meth)acrylates, and the like.

Exemplary monofunctional (meth)acrylates include those selected from a wide variety of materials, such as those represented by H₂C═CGCO₂R¹, where G may be hydrogen, halogen or alkyl groups having from 1 to about 4 carbon atoms, and R¹ here may be selected from alkyl, cycloalkyl, alkenyl, cycloalkenyl, alkaryl, aralkyl or aryl groups having from 1 to about 16 carbon atoms, any of which may be optionally substituted or interrupted as the case may be with silane, silicon, oxygen, halogen, carbonyl, hydroxyl, ester, carboxylic acid, urea, urethane, carbonate, amine, amide, sulfur, sulfonate, sulfone and the like. The monofunctional (meth)acrylates may also be hydroxyl-functional (meth)acrylates, such as hydroxyethyl acrylate, hydroxypropyl acrylate, hydroxybutyl acrylate, hydroxyethyl methacrylate (“HEMA”), hydroxypropyl methacrylate (“HPMA”), hydroxybutyl methacrylate and mixtures thereof. Other examples of suitable hydroxy functional (meth)acrylates include 2-hydroxyethyl acrylate, 2-hydroxypropyl acrylate, 2-hydroxyethyl methacrylate (“HEMA”), pentaerythritol triacrylate (“PETA”), and 4-hydroxybutyl acrylate.

Exemplary difunctional (meth)acrylates include hexanediol dimethacrylate, hydroxyacryloyloxypropyl methacrylate, hexanediol diacrylate, urethane acrylate, epoxyacrylate, bisphenol A-type epoxyacrylate, modified epoxyacrylate, fatty acid-modified epoxyacrylate, amine modified bisphenol A-type epoxyacrylate, allyl methacrylate, ethylene glycol dimethacrylate, diethylene glycol dimethacrylate, ethoxylated bisphenol A dimethacrylate, tricyclodecanedimethanol dimethacrylate, glycerin dimethacrylate, polypropylene glycol diacrylate, propoxylated ethoxylated bisphenol A diacrylate, 9,9-bis(4-(2-acryloyloxyethoxy)phenyl) fluorene, tricyclodecane diacrylate, dipropylene glycol diacrylate, polypropylene glycol diacrylate, PO-modified neopentyl glycol diacrylate, tricyclodecanedimethanol diacrylate, 1,12-dodecanediol dimethacrylate, and the like.

Exemplary trifunctional (meth)acrylates include trimethylolpropane trimethacrylate, trimethylolpropane triacrylate, trimethylolpropane ethoxy triacrylate, polyether triacrylate, glycerin propoxy triacrylate, and the like.

Exemplary polyfunctional (meth)acrylates include dipentaerythritol polyacrylate, dipentaerythritol hexaacrylate, pentaerythritol tetraacrylate, pentaerythritol ethoxy tetraacrylate, ditrimethylolpropane tetraacrylate, and the like.

Additional exemplary (meth)acrylates contemplated for use in the practice of the present invention include those described in U.S. Pat. No. 5,717,034, the entire contents of which are hereby incorporated by reference herein.

In some embodiments, the die attach adhesive layer comprises one or more fillers, such as conductive ones, like silver or copper. Examples of commercially available choices of such conductive fillers may be selected from the offerings of EA series from Metalor, and Ag-SAB silver powder series from Dowa.

In some embodiments, the die attach adhesive layer comprises silica.

In a particularly desirable embodiment, the first release substrate layer is constructed of polyester having a machine direction tensile strength at 224 MPa and cross direction tensile strength at 309 MPa, and a modulus at 538 Kpsi, having a coating of crosslinkable silicone as a release agent; the die attach adhesive layer is composed of a matrix resin comprising a combination of high molecular weight carboxyl-terminated butadiene/acrylonitrile epoxy as an epoxy resin and BMI-1700 as a maleimide resin in a by weight ratio of about 5% to about 30%; and a dicing tape layer constructed of polyolefin having a thickness of 85 micron.

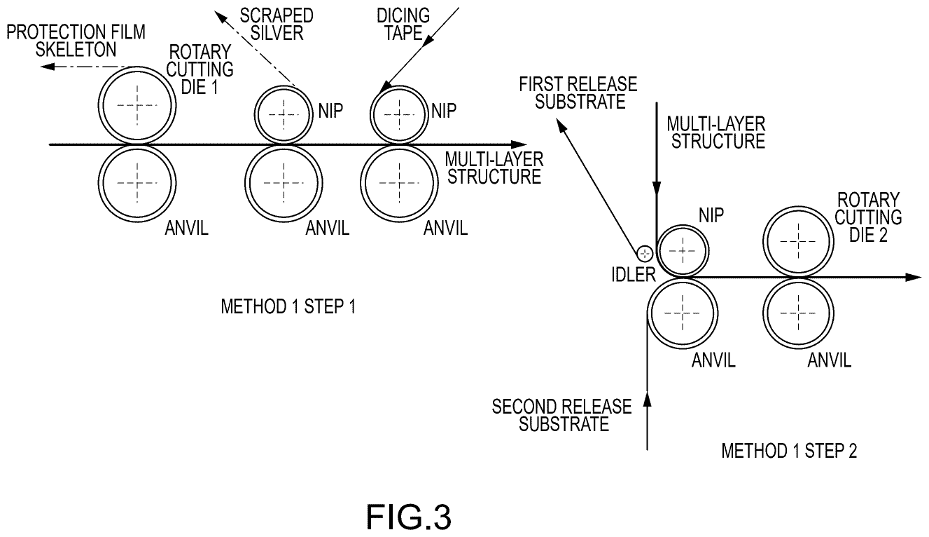

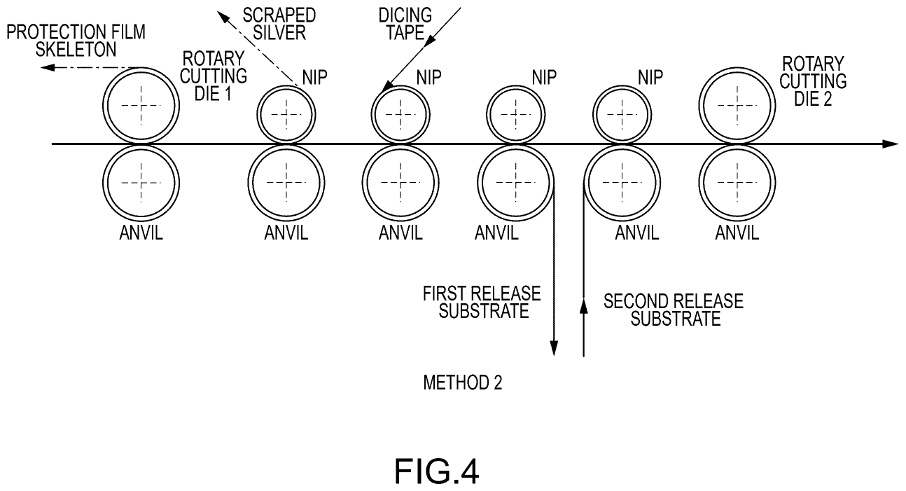

The conditions under which joining occurs of the first release substrate layer, the die attach adhesive layer, and the dicing tape layer in that order include rotary convertor operation speed of 5-25 fpm, cutting die and nip rolls pressure set point of between 50 psi to 500 psi, driven spindles tension set points of between 4 lbs to 10 lbs. In the manufacturing process an unwind spindle releases upstream coated bulk roll, a first cutting die cuts the protection film and adhesive layer to form a circle shape adhesive film sheet. See FIGS. 3 and 4 hereof.

When making the first cut, the first cutting die also makes a z-direction incision into the first release substrate. This z-direction incision has a first diameter. After the first cut is made by the first cutting die, the protection liner and adhesive film layer that remains are removed by rewinding the spindle. Then, the dicing tape is released from an unwind spindle and is laminated on the adhesive film sheet, resulting in the formation of a multi-layer structure including the first release substrate, the adhesive film sheet and the dicing tape.

The first release substrate which contains an incision mark from the first cutting die during the cutting operation is then removed and a second release substrate is released by an unwind spindle and laminated onto the adhesion film sheet and dicing tape using a nip roll of the rotary convertor.

Then the second cutting die cuts the dicing tape to overlap the dicing tape circle on the adhesive film sheet, thereby forming a multi-layer structure. This multi-layer structure includes the second release substrate (bearing no incision mark), the adhesive film sheet and the dicing tape. This operation may occur at a rotary convertor operation speed of 5-25 fpm, and the cutting die and nip roller pressure set between 50 psi to 500 psi. The driven spindles tension may be set between 4 lbs to 10 lbs.

Provided herein in another aspect is a method for producing a semiconductor chip. In the method of this aspect, the steps include:
A1. Providing a die attach adhesive film sheet made by the method described in the preceding paragraphs;
B1. Peeling away the second release substrate from the die attach adhesive film sheet to reveal the die attach adhesive film layer; and
C1. Providing a semiconductor wafer having a surface available for bonding and mating the surface of the semiconductor wafer available for bonding to the die attach adhesive film sheet through the die attach adhesive layer thereof.

The die attach adhesive film sheet layer is as described above.

The second release substrate is as described above.

The semiconductor wafer may be an 8″ or 12″ inch diameter silicon wafer, having a thickness ranging from 80 micron to 200 micron. The backside of the silicon wafer is smooth allowing the die attach adhesive sheet to be laminated thereon.

In some embodiments, the method further includes the step of:
D1. Dicing the semiconductor wafer having the die attach adhesive film mated to a surface of the semiconductor water to yield a semiconductor element having a die attach adhesive film of a pre-determined size available for further bonding.

The semiconductor wafer on which the die attach adhesive film is disposed may have dimensions of 2×2 millimeter to 8×8 millimeter range to yield a semiconductor element.

The semiconductor element (or, semiconductor die) is separated from a wafer using the dicing process. The dicing process includes scribing the wafer in a predetermined pattern and then breaking (e.g., mechanical sawing using a dicing saw or by laser cutting) the scribed wafer into individual die. In the case of a dicing saw, 15,000 to 30,000 rpm spinning speed is ordinarily used.

In some embodiments, the method further includes the step of:
E1. Bonding the semiconductor element having the die attach adhesive layer exposed for bonding through the die attach adhesive layer to a carrier substrate to form a semiconductor package or semiconductor assembly.

The semiconductor package or semiconductor assembly are typically used in quad flat no-lead packages (or, QFN) or then quad flat no-lead packages (or, TQFN). These packages are leadless and are small in size, while offering moderate heat dissipation in PCBs. Like any other IC package, the function of a QFN package is to connect the silicon die of the IC to the circuit board.

The die attach (bonding) curing conditions are as follows: 30 minute ramp from 25 C to 200 C, and then holding at 200 C for 60 minutes. Alternatively, 30 minute ramp from 25 C to 175 C, and then holding at 175 C for 60 minutes.

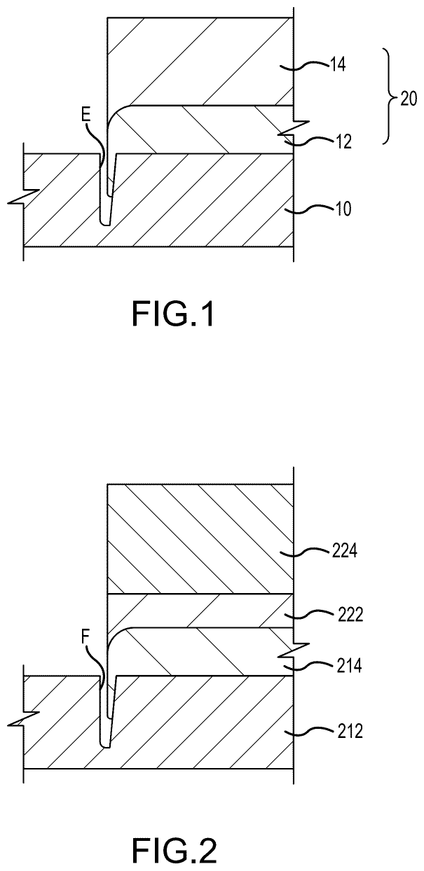

Use of known wafer lamination techniques have reported failure rates as high as 50%. Indeed, with reference to FIGS. 1 and 2 hereof, in which the techniques described in U.S. Pat. No. 8,470,115 (Tanaka) (such as is shown in FIGS. 15 and 25 thereof and supporting description therein) are illustrated, the first incision formed in the release substrate caused the adhesive layer to not be fully laminated on the back side of the wafer. More specifically, the adhesive sheet may be torn during the wafer lamination process, where portions of the adhesive sheet remain on the release substrate resulting in failure during the adhesive sheet wafer lamination process. Under certain lamination conditions (such as a lamination speed of less than or equal to 10 mm/s), the failure rate can be as high as 50%.

In contrast, the inventive method described and claimed herein, reduces failure rate dramatically. More specifically, with reference to FIGS. 3 and 4, as the first release substrate is replaced by a second release substrate that contains no incision mark, under the same wafer lamination conditions, a failure rate as low as 0% may be reached. Indeed, of 320 sheets made in this manner and evaluated under lamination conditions of less than or equal to 10 mm/s, no defects were observed.

What is claimed is:

1. A method for producing a die attach adhesive film sheet, comprising:
A. Providing a first release substrate layer, a die attach adhesive layer, and a dicing tape layer, and joining the first release substrate layer, the die attach adhesive layer, and the dicing tape layer in that order to form a multi-layer structure (i);
B. Working the multi-layer structure (i) to form a circular preformed die attach adhesive film sheet, wherein during said working the first release substrate receives a z-directional indentation therein, wherein the z-direction indentation has a first diameter; and
C. Removing the first release substrate with the z-directional indentation therein from the die attach adhesive layer, and placing in its stead a second release substrate in contact with the die attach adhesive layer to form a multi-layer structure (ii).

2. The method of claim 1, further comprising
D. Working the multi-layer structure (ii) to receive a z-directional indentation in the second release substrate, wherein the z-directional indentation has a second diameter, wherein the second diameter is greater than the first diameter.

3. The method of claim 1, wherein the first release substrate is constructed from polyester, which optionally is coated by a release agent.

4. The method of claim 1, wherein the second release substrate is constructed from polyester, which optionally is coated by a release agent.

5. The method of claim 1, wherein the first release substrate is from about 35 μm to about 50 μm in thickness.

6. The method of claim 1, wherein the second release substrate is from about 35 μm to about 50 μm in thickness.

7. The method of claim 1, wherein the dicing tape layer is constructed from PVC, polyolefin or polyethylene.

8. The method of claim 1, wherein the dicing tape layer is from about 80 micron to about 150 micron in thickness.

9. The method of claim 1, wherein the die attach adhesive layer comprises a curable matrix comprising at least one of epoxy resins; maleimide-containing, nadimide-containing and/or itaconimide-containing resins; and/or (meth)acrylate resins.

10. The method of claim 1, wherein the die attach adhesive layer comprises one or more fillers.

11. The method of claim 1, wherein the die attach adhesive layer comprises silica.

12. The method of claim 1, wherein the die attach adhesive layer comprises conductive fillers.

13. The method of claim 1, wherein the die attach adhesive layer comprises silver.

14. A method for producing a semiconductor chip, comprising:
A1. Providing a die attach adhesive film sheet made by the method of claim 1;
B1. Peeling away the second release substrate from the die attach adhesive film sheet to reveal the die attach adhesive film layer; and
C1. Providing a semiconductor wafer having a surface available for bonding and mating the surface of the semiconductor wafer available for bonding to the die attach adhesive film sheet through the die attach adhesive layer thereof.

15. The method claim 14, further comprising:
D1. Dicing the semiconductor wafer having the die attach adhesive film mated to a surface of the semiconductor wafer to yield a semiconductor element having a die attach adhesive film of a pre-determined size available for further bonding.

16. The method of claim 15, further comprising:
E1. Bonding the semiconductor element having the die attach adhesive layer exposed for bonding through the die attach adhesive layer to a carrier substrate to form a semiconductor package or semiconductor assembly.
